(19) United States
(12) Patent Application Publication
(10) Pub. No.: US 2025/0285875 A1
(43) Pub. Date: Sep. 11, 2025

(54) SUBSTRATE PROCESSING METHOD AND SUBSTRATE PROCESSING APPARATUS

(71) Applicant: Tokyo Electron Limited, Tokyo (JP)

(72) Inventors: Takuji SAKO, Leuven (BE); Tsubasa KAWAGUCHI, Nirasaki City (JP); Noriyuki KOBAYASHI, Nirasaki City (JP); Tomoya TERAGUCHI, Nirasaki City (JP); Daiki ASAKAWA, Nirasaki City (JP); Tomoya OKUBO, Nirasaki City (JP)

(21) Appl. No.: 19/074,722

(22) Filed: Mar. 10, 2025

(30) Foreign Application Priority Data
Mar. 11, 2024 (JP) 2024-037490
Dec. 3, 2024 (JP) 2024-210675

(51) Int. Cl. H01L 21/311; H01L 21/02; H01L 21/67

(52) U.S. Cl. CPC H01L 21/31116; H01L 21/0214; H01L 21/0223; H01L 21/67069; H01L 21/67126

(57) ABSTRACT

A substrate processing method of supplying a process gas to a substrate, in which a first film and a second film that are silicon-containing films of different types are exposed on a surface, to selectively etch the first film that is a silicon oxide film, the method including: a protection process of supplying a fluid containing a silylating agent to the substrate in order to form, on a surface layer of the second film, a protective film that prevents etching of the second film; and an etching process of selectively etching the first film by supplying the process gas to the substrate having the protective film formed thereon.

### CROSS-REFERENCE TO RELATED APPLICATION

This application is based upon and claims the benefit of priority from Japanese Patent Application Nos. 2024-037490 and 2024-210675, filed on March 11 and Dec. 3, 2024, respectively, the entire contents of which are incorporated herein by reference.

### TECHNICAL FIELD

The present disclosure relates to a substrate processing method and a substrate processing apparatus.

### BACKGROUND

In the manufacture of a semiconductor device, a silicon oxide film formed on a surface of a semiconductor wafer (hereinafter referred to as a wafer), which is a substrate, may be etched. Patent Document 1 describes a technique including a first modifying process using a HF gas and a NH₃ gas and a second modifying process using a HF gas in etching in which modifying a silicon oxide film and then heating a reaction product produced by the modification to remove it are performed. In addition, Patent Document 2 describes a technique of etching a silicon oxide film while protecting it by forming a protective film made of amine on the silicon oxide film. Patent Document 3 describes an apparatus for performing plasma processing on a substrate, in which a protective film, which is a water-repellent silicon-containing film, is formed on each component in a processing chamber by forming a plasma of TMSDMA gas, thereby preventing adhesion of moisture to each component during maintenance of the apparatus.

### PRIOR ART DOCUMENTS

### Patent Documents

Patent Document 1: Japanese Patent Publication No. 6812284
Patent Document 2: Japanese Patent Laid-Open Publication No. 2021-174938
Patent Document 3: Japanese Patent No. 7357182

### SUMMARY

According to one embodiment of the present disclosure, there is provided a substrate processing method of supplying a process gas to a substrate, in which a first film and a second film that are silicon-containing films of different types are exposed on a surface, to selectively etch the first film that is a silicon oxide film, the method including: a protection process of supplying a fluid containing a silylating agent to the substrate in order to form, on a surface layer of the second film, a protective film that prevents etching of the second film; and an etching process of selectively etching the first film by supplying the process gas to the substrate having the protective film formed thereon.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1A is a longitudinal side view of a wafer undergoing a process according to an embodiment of the present disclosure.

FIG. 1B is a longitudinal side view of the wafer.

FIG. 2A is a longitudinal side view of the wafer.

FIG. 2B is a longitudinal side view of the wafer.

FIG. 3 is a chemical reaction formula illustrating a reaction proceeding in a protection process.

FIG. 4 is a plan view illustrating an embodiment of a substrate processing apparatus for performing the processing.

FIG. 5 is a longitudinal side view illustrating an example of a processing module provided in the substrate processing apparatus.

FIG. 6 is a chart showing a timing of supply of each gas.

FIG. 7 is characteristic diagram illustrating results of an evaluation test.

FIG. 8 is a graph showing the results of the evaluation test.

FIG. 9 is a graph showing the results of the evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

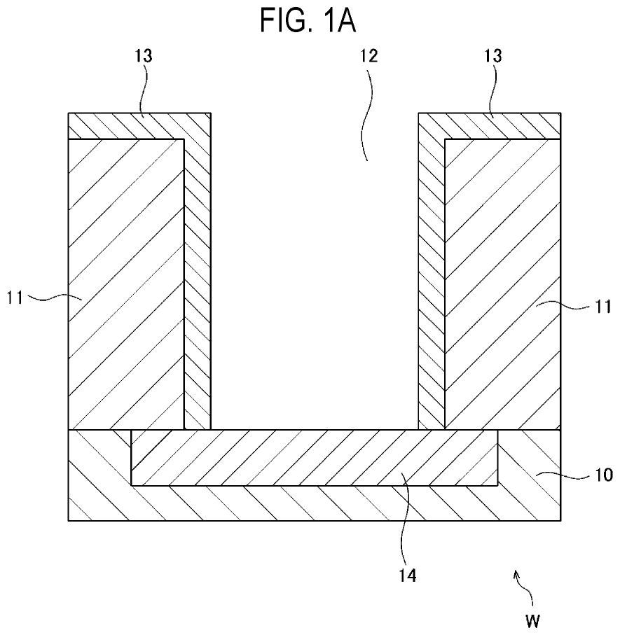

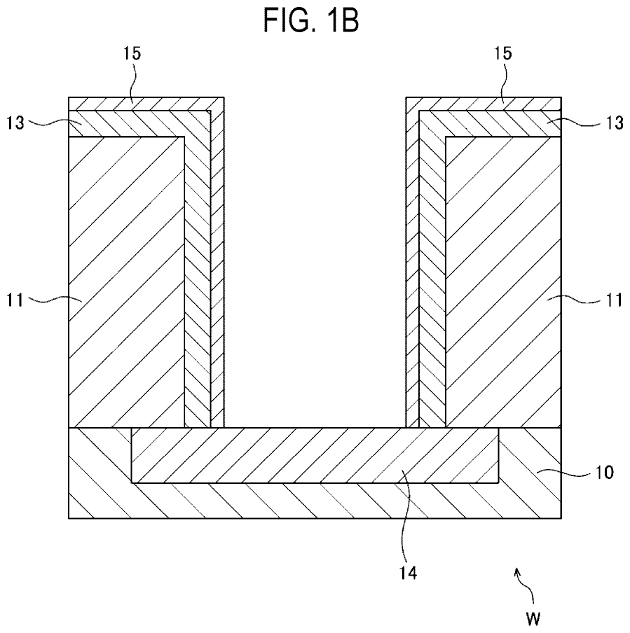

An outline of a processing, which is an embodiment of a substrate processing method of the present disclosure, will be described. FIG. 1A is a longitudinal side view of a surface of a wafer W which is a substrate before a processing. The wafer W has a silicon (Si) layer 10.

Above the Si layer 10, structures consisting of an upper layer film 11 and a SiN film 13 that covers and surrounds the upper layer film 11 from the top surface to the side surface are formed at regular intervals, and FIGS. 1A and 1B shows a recess 12 sandwiched between one structure and another structure adjacent to each other. A SiO₂ film (silicon oxide film) 14 is formed on the bottom of the recess 12. Portions of the SiO₂ film 14 are formed below the upper layer film 11 and the SiN film 13, and the other portion is formed on the bottom surface of the recess 12. Further, the SiO₂ film 14 is formed below one structure and the other structure, so that the portions thereof are covered by each structure, and the other portion is exposed to the surface of the wafer W as the bottom surface of the recess 12. The recess 12 has a structure with a relatively high ratio (D/W) of the depth D and the opening width W, and that is, is formed to have a high aspect ratio. For example, the opening width W may be 25 nm. The recess 12 is used as a contact hole, for example.

The SiO₂ film 14 is a first film, and the SiN film 13 is a second film. As such, the first film and the second film, which are silicon-containing films of different types, are exposed on the surface of the wafer W which is a substrate. As the SiO₂ film 14, for example, oxide films formed by various methods such as a thermal oxide film, an oxide film formed by a CVD method, and an oxide film formed using a tetraethoxysilane (TEOS) raw material may be used.

In the present embodiment, among the SiN film 13 and the SiO₂ film 14, the SiO₂ film 14 is selectively etched by supplying a process gas. As described above, the portions of the SiO₂ film 14 are formed below the structure consisting of the SiN film 13 and the upper layer film 11, and thus, the etching is performed by supplying the process gas to the SiO₂ film 14 through the recess 12. Due to diffusion of the process gas, the process gas is also supplied from the side to the portions of the SiO₂ film 14 formed below the structures, and the portions are also etched.

As for the etching of the SiO₂ film 14, even if the process gas, which is originally capable of selectively etching the SiO₂ film 14 among the SiO₂ film 14 and the SiN film 13, is used, the SiN film 13 may also be etched together with the SiO₂ film 14. It is presumed that this is because a surface layer is oxidized by a processing performed until the etching of the SiO₂ film is performed, thus having properties similar to those of the SiO₂ film 14. Since the etching of the SiN film 13 increases the line width of a pattern and shortens the distance between patterns, there is a risk of an increase in leakage current or a short-circuit resulting therefrom. That is, there is a risk of ultimately lowering the yield of semiconductor devices manufactured from the wafer W. A processing in the present embodiment is performed so as to be able to cope with these problems.

Next, a processing performed on the wafer W will be described in order with reference to FIGS. 1B to 3. The processing illustrated in each drawing is performed in a state where the wafer W is loaded into a processing container and the interior of the processing container is evacuated to a vacuum atmosphere at a predetermined pressure. During the processing, the wafer W is adjusted to a desired temperature.

First, a protection process will be described. In this process the interior of the processing container is evacuated to, e.g., 5.0 Pa to 40.0 Pa and a temperature of the wafer W is adjusted to, e.g., 20 degrees C. to 120 degrees C. Once the internal pressure of the processing container and the temperature of the wafer W are adjusted as described above, a gas containing a silylating agent is supplied into the processing container. As the silylating agent, a compound containing silicon (Si) and an alkyl group, e.g., trimethylsilyldimethylamine (TMSDMA) may be used. In this example, a TMSDMA gas is supplied into the processing container, and the SiN film 13 is silylated with this gas, so that a protective film 15 is formed on the surface layer of the SiN film 13, as illustrated in FIG. 1B.

It is presumed in the protection process that a chemical reaction illustrated in FIG. 3 proceeds in the surface layer of the SiN film 13 to form the protective film 15. As illustrated in FIG. 3, in the surface layer of the SiN film 13, parts of Si—N bonds are broken, and a hydroxyl group (—OH) bonds to Si to form a Si—OH bond. Therefore, since the surface layer of the SiN film 13 contains oxygen (O), it is considered that the surface layer has properties similar to those of an oxide film as described above.

In a chemical reaction formula illustrated in FIG. 3, the silylating agent is SiR₃X. R is an alkyl group, and when the silylating agent is TMSDMA, R is a methyl group (—CH₃) and X is an amino group (—N(CH₃)₂). Then, when the TMSDMA gas is supplied to the SiN film 13, a chemical reaction proceeds to replace hydrogen (H) of the hydroxyl group (—OH) bonded to Si by a trimethylsilyl group (—Si(CH₃)₃), so that the protective film 15 is formed. On the other hand, H released from the Si—OH bond bonds with an amino group (—N(CH₃)₂) to produce a dimethylamine (NH(CH₃)₂) gas, which is removed by evacuating the interior of the processing container.

The protective film 15 formed in this way is a film made by the change of the surface layer of the SiN film 13, and a film thickness of the SiN film 13 including the protective film 15 hardly changes before and after the protective film 15 is formed. However, since the OH group of the SiN film 13 containing oxygen in the surface layer is hydrophilic and the trimethylsilyl group is hydrophobic, the surface layer of the SiN film 13 is made hydrophobic by the formation of the protective film 15.

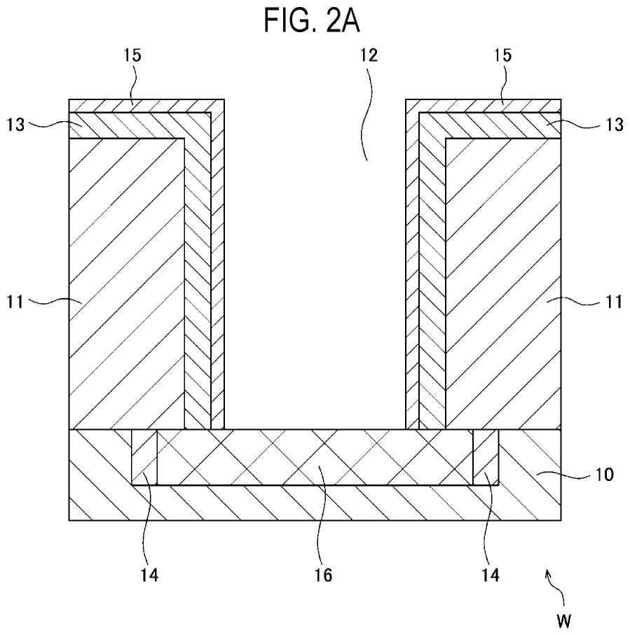

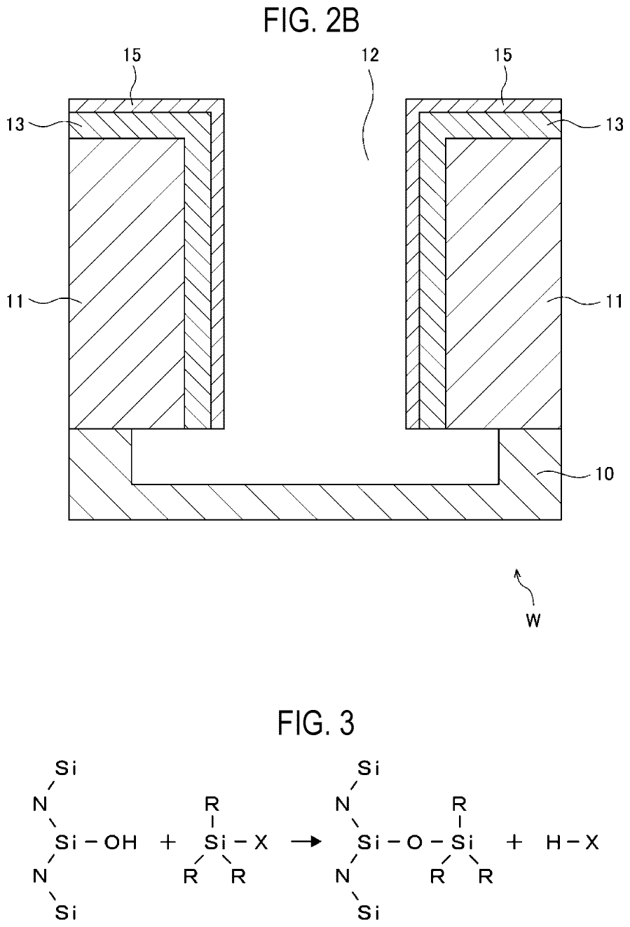

In the protection process, the TMSDMA gas is supplied into the processing container, so that not only the SiN film 13 but also the SiO₂ film 14 exposed to the recess 12 come into contact with the TMSDMA gas and are silylated. However, it is presumed that the influence of the silylating agent on the SiO₂ film 14 is small since it has been confirmed that the SiO₂ film 14 is etched in an etching process to be described later even after the protection process is performed. Therefore, in FIGS. 1B and 2A, the protective film 15 is illustrated only on the surface layer of the SiN film 13. In addition, since the reaction proceeds as described with reference to FIG. 3, it is presumed that the protective film 15 is formed so as to correspond to an oxidized portion of the SiN film 13. Thus, although FIGS. 1B and 2A illustrate that the entire surface layer of the SiN film 13 is changed to the protective film 15, it is considered that the protective film 15 may be formed locally.

Next, an etching process performed after the protection process will be described. The etching process in this example includes a modifying process of supplying a process gas to modify the SiO₂ film 14 which is the first film, and a heating process of heating the wafer W to sublimate and remove the modified SiO₂ film 14. In this example, the modifying process and the protection process are performed on the wafer W within the same processing container.

In the modifying process, the interior of the processing container is evacuated to, e.g., 5.0 Pa to 40.0 Pa and the temperature of the wafer W is adjusted to, e.g., 20 degrees C. to 120 degrees C. Once the internal pressure of the processing container and the temperature of the wafer W are adjusted as described above, a hydrogen fluoride (HF) gas and an ammonia (NH₃) gas are supplied as a process gas for etching. As such, by supplying these gases to the surface of the wafer W, a first chemical oxide removal (COR) processing is performed on the wafer W. In the first COR processing, the internal pressure of the processing container is adjusted to, e.g., 5.0 Pa to 40.0 Pa and the temperature of the wafer W is adjusted to, e.g., 20 degrees C. to 120 degrees C.

In the first COR processing, the SiO₂ film 14 existing at the bottom of the recess 12 of the wafer W is modified by a chemical reaction with molecules of the HF gas and molecules of the NH₃ gas, thereby changing to a reaction product (see FIG. 2A). This chemical reaction proceeds, in the downward direction and the horizontal direction, inward from a surface of the SiO₂ film 14 exposed to the recess 12 (toward a side away from the surface), and ammonium fluorosilicate (AFS), moisture and the like are produced as a reaction product.

Subsequently, in the modifying process of the present embodiment, after the first COR processing is performed, a second COR processing is also performed on the wafer W. In the second COR processing, only the HF gas is supplied to the wafer W without using the NH₃ gas which is a basic gas. By supplying the HF gas, the SiO₂ film 14 is modified at an interface of the reaction product (first reaction product) generated in the first COR processing and the SiO₂ film 14 inward of the first reaction product in the horizontal direction, thereby producing a second reaction product.

The second reaction product contains dihydrogenhexafluorosilicate (H₂SiF₆) and the like, and is produced by a chemical reaction with molecules of the HF gas using the moisture contained in the first reaction product as a catalyst. FIG. 2A shows a state in which a first reaction product and a second reaction product are generated by performing a first COR processing and a second COR processing, wherein the first reaction product and the second reaction product are not distinguished from each other and are collectively referred to as reaction product 16.

In the second COR processing, the HF gas is supplied without supplying the NH₃ gas, so that the HF gas easily permeates through the first reaction product, thereby being capable of producing the second reaction product inward of the SiO₂ film 14. This second COR processing is performed in the same processing container as in the first COR processing, and the internal pressure of the processing container and the temperature of the wafer W in the second COR processing are set, for example, in the same manner as in the first COR processing.

Once a sufficient layer of the second reaction product is formed and the second COR processing is completed, the heating process is performed. In this example, this heating process is performed in a different processing container from the processing container in which the first COR processing and the second COR processing were performed. In the heating process, a high-temperature heating gas is supplied into the processing container while evacuating the interior of the processing container. Thus, the reaction product (the first reaction product and the second reaction product) generated by the COR processing are heated and vaporized, and pass through the recess 12 from below the recess 12 to thereby be discharged to the outside of the wafer W. In this way, as illustrated in FIG. 2B, by performing the heating process after the first COR processing and the second COR processing, the reaction product 16 is removed, so that the SiO₂ film 14 can be etched.

As described above, the influence of the silylating agent on the surface layer of the SiO₂ film 14 is small in the protection process, and therefore, the first COR processing and the second COR processing proceed quickly. On the other hand, since the protective film 15 is formed on the surface layer of the SiN film 13, the protective film 15 prevents the SiN film 13 from coming into contact with the process gas (HF gas and NH₃ gas), which prevents the production of the reaction product 16 in the SiN film 13.

As illustrated in FIG. 3, oxygen (O) exists in the surface layer of the SiN film 13 even after the protective film 15 is formed, and silicon (Si) bonds to the oxygen to form a siloxane bond (Si—O—Si). From the viewpoint of the process gas, it is considered that an oxidized portion of the SiN film 13 is in a state as if it were coated and masked and that portion is also in a state as if it were repaired by Si which is a constituent element of the SiN film 13, so that the reactivity of the process gas and the oxidized portion is reduced. Therefore, the formation of the protective film 15 prevents the etching of the SiN film 13.

In addition, as already described, the protective film 15 is also formed on the surface layer of the SiO₂ film 14, so that the etching rate of the SiO₂ film 14 in the etching process is lowered compared to a case where the protection process is not performed. Thus, in order to obtain the etching amount of the SiO₂ film 14 to a set amount, the etching processing time is prolonged compared to a case where the protection process is not performed. It has been confirmed that even in such a case, the amount of loss (etching amount) of the SiN film 13 is smaller than in a case where the protection process is not performed.

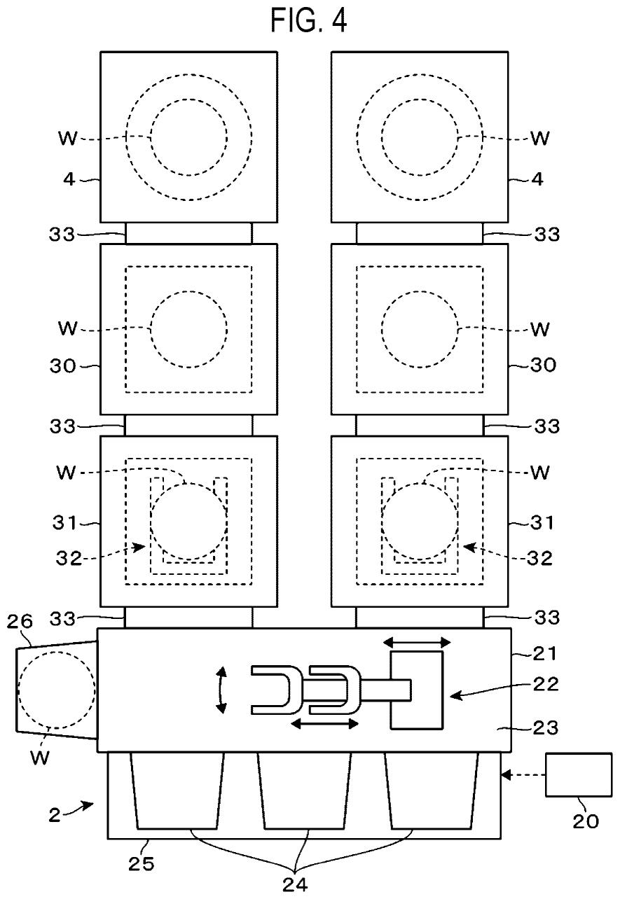

Next, an embodiment of a substrate processing apparatus 2 that performs a series of processes described with reference to FIGS. 1A to 2B will be described with reference to a plan view of FIG. 4. The substrate processing apparatus 2 includes a loading/unloading section 21 for loading and unloading the wafer W, two load lock chambers 31 provided adjacent to the loading/unloading section 21, two thermal processing modules 30 provided respectively adjacent to the two load lock chambers 31, and two processing modules 4 provided respectively adjacent to the two thermal processing modules 30.

The loading/unloading section 21 includes a normal-pressure transfer chamber 23 which is provided with a first substrate transfer mechanism 22 and is under a normal-pressure atmosphere, and a carrier placing table 25 which is provided on the side of the normal-pressure transfer chamber 23, on which a carrier 24 accommodating the wafers W therein is placed. Reference numeral 26 in the drawing denotes an aligner adjacent to the normal-pressure transfer chamber 23. The aligner 26 is provided for rotating the wafer W to optically obtain the amount of eccentricity thereof, thereby aligning the position of the wafer W with respect to the first substrate transfer mechanism 22. The first substrate transfer mechanism 22 transfers the wafer W between the carrier 24 on the carrier placing table 25, the aligner 26, and the load lock chambers 31.

In each load lock chamber 31, a second substrate transfer mechanism 32 having, for example, a multi-joint arm structure is provided. The second substrate transfer mechanism 32 transfers the wafer W between the load lock chambers 31, the thermal processing modules 30, and the processing modules 4. The interior of a processing container constituting the thermal processing module 30 and the interior of a processing container constituting the processing module 4 are under a vacuum atmosphere. The interior of the load lock chamber 31 is switched between the normal-pressure atmosphere and the vacuum atmosphere so that the wafer W may be transferred between the interior of the processing container in the vacuum atmosphere and the normal-pressure transfer chamber 23.

Reference numeral 33 in the drawing denotes gate valves that may be opened and closed and are provided respectively between the normal-pressure transfer chamber 23 and the load lock chambers 31, between the load lock chambers 31 and the thermal processing modules 30, and between the thermal processing modules 30 and the processing modules 4. The thermal processing module 30 includes the aforementioned processing container, an exhaust mechanism for evacuating the interior of the processing container to create the vacuum atmosphere, a stage provided in the processing container and capable of heating the wafer W placed thereon, and the like. The thermal processing module 30 is configured to be capable of performing the heating process described already.

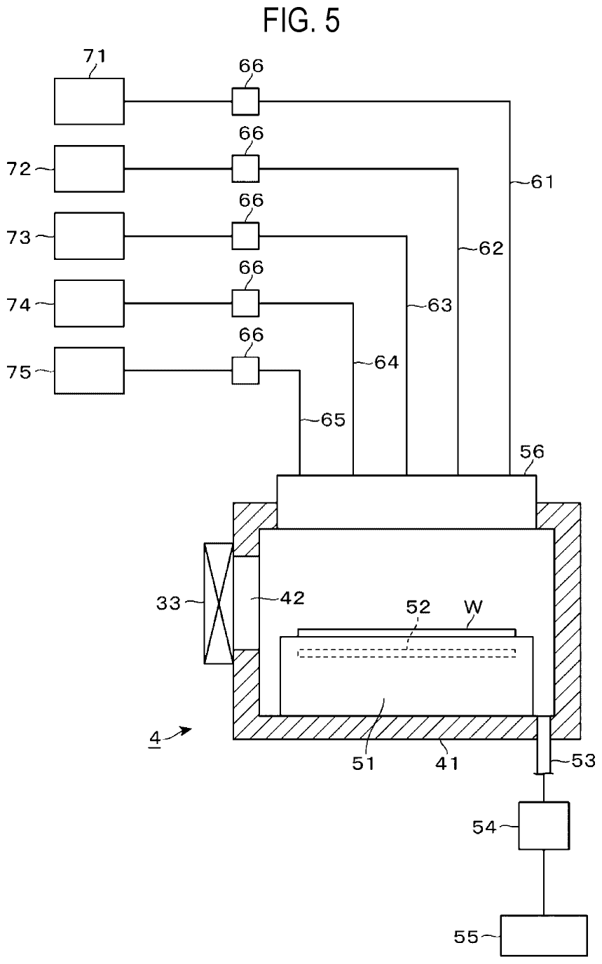

The processing module 4 will be described with reference to a longitudinal side view of FIG. 5. This processing module 4 performs the protection process and the modifying process (first COR processing and second COR processing) described already. Reference numeral 41 in the drawing denotes the processing container constituting the processing module 4. A transfer port 42 for the wafer W is open in a sidewall of the processing container 41. The transfer port 42 is opened and closed by the above-described gate valve 33. A stage 51 on which the wafer W is placed is provided within the processing container 41. The stage 51 has lifting pins (not illustrated) for transferring the wafer W to and from the second substrate transfer mechanism 32.

A temperature adjuster 52 is embedded in the stage 51, and the wafer W placed on the stage 51 is set to the temperature described already. The temperature adjuster 52 is configured, for example, as a flow path that forms a part of a circulation path, through which a temperature adjustment fluid such as water flows, and adjusts the temperature of the wafer W by heat exchange with the fluid. However, the temperature adjuster 52 is not limited to such a fluid flow path, and may be configured by, for example, a heater for performing resistance heating.

Further, one end of an exhaust pipe 53 is open within the processing container 41, and the other end of the exhaust pipe 53 is connected to an exhaust mechanism 55 configured by, for example, a vacuum pump. The exhaust pipe 53 includes a valve 54 which is a pressure change mechanism. By adjusting the opening degree of the valve 54, the internal pressure of the processing container 41 reaches the above-described pressure range to enable the implementation of a processing.

A gas shower head 56 is provided on the top side within the processing container 41 so as to face the stage 51. The gas shower head 56 is connected to the downstream side of gas supply paths 61 to 65, and the upstream side of the gas supply paths 61 to 65 are connected respectively to gas sources 71 to 75 via respective flow rate regulators 66. Each flow rate regulator 66 includes a valve and a mass flow controller. As for a gas supplied from each of the gas sources 71 to 75, it is supplied to the downstream side, or stopped by opening or closing the valve included in the corresponding flow rate regulator 66.

A TMSDMA gas, which is the silylating agent, a HF gas, a NH₃ gas, an argon (Ar) gas, and a nitrogen (N₂) gas are respectively supplied from the gas sources 71, 72, 73, 74, and 75. These gases are respectively supplied into the processing container 41 through the gas shower head 56. The Ar gas and the N₂ gas are used as a carrier gas.

TMSDMA is a liquid at room temperature, and in the protection process, is supplied into the processing container 41 together with the carrier gas by, for example, heating a container accommodating the TMSDMA to vaporize the TMSDMA and supplying the carrier gas into that container. In this example, a fluid supplier for the formation of the protective film includes the gas source 71, the gas supply path 61, the flow rate regulator 66 provided in the gas supply path 61, and the gas shower head 56. Further, the HF gas and the NH₃ gas in the first COR processing and the HF gas in the second COR processing are supplied into the processing container 41 together with the carrier gas. In this example, a process gas supplier includes the gas sources 72 and 73, the gas supply paths 62 and 63, the flow rate regulators 66 provided in the gas supply paths 62, 63, respectively, and the gas shower head 56. An inert gas supplier includes the gas supply sources 74, 75, the gas supply paths 64, 65, and the flow rate regulators 66 provided in the gas supply paths 64, 65, respectively, and the gas shower head 56.

As illustrated in FIG. 4, the substrate processing apparatus 2 includes a controller 20 which is a computer. The controller 20 includes a program, a memory, and a CPU. The program incorporates instructions (each process) to perform the above-described processing of the wafer W and the transfer of the wafer W. This program is stored in a non-transitory computer-readable storage medium such as, for example, a compact disk, a hard disk, a magneto-optical disk, and a DVD, and is installed in the controller 20. The controller 20 outputs control signals to each part of the substrate processing apparatus 2 according to the program to control the operation of each part. Specifically, the operation of the processing module 4, the operation of the thermal processing module 30, the operation of the first substrate transfer mechanism 22 and the second substrate transfer mechanism 32, and the operation of the aligner 26 are controlled by the control signals. Examples of the operation of the processing module 4 controlled by the control signals may include the adjustment of the temperature of a fluid supplied to the stage 51, the supply/stop of each gas from the gas shower head 56 and the adjustment of the flow rate of each gas supplied to the processing container 41 by the flow rate regulator 66, the adjustment of the exhaust flow rate by the valve 54, and the like.

A transfer route of the wafer W in the substrate processing apparatus 2 will be described. As described with reference to FIG. 1A, the carrier 24 accommodating the wafers W, on which each film is formed, is placed on the carrier placing table 25. Then, the wafer W is transferred in the order of the normal-pressure transfer chamber 23→the aligner 26→the normal-pressure transfer chamber 23→the load lock chamber 31 and is transferred to the processing module 4 through the thermal processing module 30. Then, as described already, the TMSDMA gas is supplied to perform the processing described as the protection process, thereby forming the protective film 15.

Subsequently, in the processing module 4, the supply of the TMSDMA gas is stopped, and the TMSDMA gas is discharged from the processing container 41. Then, as described already, the HF gas and the NH₃ gas are supplied as the process gas to perform the first COR processing, thereby forming the first reaction product (AFS layer). Thereafter, the supply of the NH₃ gas is stopped and only the HF gas is supplied as the process gas to perform the second COR processing, thereby forming the second reaction product.

Next, the wafer W is transferred to the thermal processing module 30, the heating process is performed to sublimate the reaction product 16. Thus, part of the SiO₂ film 14 is selectively etched. In addition, by transferring the wafer W back and forth between the processing module 4 and the thermal processing module 30, the cycle of the protection process→the first COR processing→the second COR processing→the heating process may be repeatedly performed a predetermined number of times. Thereafter, the wafer W is transferred from the thermal processing module 30 in the order of the load lock chamber 31→the normal-pressure transfer chamber 23, and is returned to the carrier 24. A supplementary explanation will be given regarding the repetition of the above cycle. FIGS. 1A and 1B and FIGS. 2A and 2B depict that the processing gas permeates the SiO₂ film 14 laterally, and the SiO₂ film 14 is modified, and the portions of the SiO₂ film 14 located below the upper layer film 11 and the SiN film 13 are also etched. The processing may proceed such that the SiO₂ film 14 exposed at the bottom surface of the recess 12 is first etched downward, the depth of the recess 12 increases, and a space is formed in the portions of the SiO₂ film 14 located below the upper layer film 11 and the SiN film 13, by repeating the cycle without the processing gas permeating in that way. Then, in the next cycle, the processing gas is supplied laterally through this space to the portions of the SiO₂ film 14 located below the upper layer film 11 and the SiN film 13, and the portions are etched. The protection process may be performed only once, and the etching process (first COR process second COR process→heating process) may be performed repeatedly.

According to the processing method illustrated in the present embodiment, as described above, in the wafer W in which the SiO₂ film 14 as the first film and the SiN film 13 as the second film are exposed on the surface thereof, the protective film 15 is formed on the surface layer of the SiN film 13, so that the SiO₂ film 14 may be selectively etched. As such, the etching of the SiN film 13 is prevented by the protective film 15, so that a change in the shape of the recess 12 is prevented during the etching of the SiO₂ film 14. Therefore, an increase in leakage current and the occurrence of a short circuit resulting therefrom may be prevented, which may increase the yield of semiconductor products manufactured from the wafer W after the etching process.

Further, in the above-described embodiment, the protection process and the modifying process are performed on the wafer W within the same processing container using the gas containing the silylating agent. Therefore, the size of the substrate processing apparatus 2 may be reduced compared to a case where these processes are performed respectively in different processing containers. Further, since it is not necessary to transfer the wafer W to another processing container in which the modifying process is performed after performing the protection process on the wafer W, the throughput may be improved, which may further increase the yield of semiconductor products. When the protection process and the modifying process are performed within the same processing container as described above, the processing may be performed while maintaining a constant processing temperature of the wafer W (i.e., a constant temperature of the stage 51). That is, the throughput may be increased by promptly starting the modifying process without changing the temperature of the stage 51 after the protection process is completed.

As the silylating agent for forming the protective film 15, dimethylsilyldimethylamine (DMSDMA), hexamethyldisilazane (HMDS), tetramethyldisilazane (TMDS), TMSPyrole (1-trimethylsilylpyrole), BSTFA(N,O-Bis(trimethylsilyl)trifluoroacetamide), BDMADMS(Bis(dimethylamino)dimethylsilane), and the like may be used, in addition to TMSDMA. In addition, for convenience, FIG. 3 illustrates the silylating agent as SiR₃X. Although all three Rs of SiR₃X are alkyl groups for TMSDMA, the present disclosure is not limited to the use of the silylating agent in which all of the three Rs are alkyl groups and may use a silylating agent in which one or more of the Rs are halogenated alkyl groups. The halogenated alkyl group as used herein is an alkyl group in which one or more hydrogen atoms are replaced by halogen atoms. Further, for DMSDMA exemplified as the silylating agent, one of the three Rs is represented as H (hydrogen atom). As such, the silylating agent may be a compound in which some of the three Rs are H.

In the above, a fluid containing the silylating agent may be a liquid containing the silylating agent. For example, the protective film 15 is formed by coating the surface of the wafer W with the liquid by a method such as spin coating under an air atmosphere. Thereafter, the wafer W may be transferred to the substrate processing apparatus 2 for a subsequent processing. In addition, when dropping the TMSDMA liquid onto the surface of the oxidized SiN film 13 and measuring the contact angle before and after the protection process, it was confirmed that the contact angle after the formation of the protective film 15 was about 5 times larger than that before the formation of the protective film 15, and the SiN film 13 was hydrophobic. That is, the formation of the protective film 15 by silylation described with reference to FIG. 3 was confirmed.

Further, the present disclosure is not limited to the use of the HF gas in the modifying process, and a similar processing may be performed by using, for example, a F2 gas, IF₇ gas, IF₅ gas, ClF₃ gas, or SF₆ gas to modify the SiO₂ film as the first film to produce a reaction product. As such, various fluorine-containing gases may be used. Furthermore, in the processing example described above, the first COR processing and the second COR processing were performed in the modifying process when etching the SiO₂ film 14, but only the first COR processing may be performed. Further, the method of the present disclosure is not limited to the horizontal etching of the SiO₂ film 14 in the above-described device structure. For example, the method of the present disclosure may also be used when the SiO₂ film 14 and the SiN film 13 are arranged in the horizontal direction and are formed on the wafer W such that an upper surface of each film is exposed, and the SiO₂ film 14 is etched from above.

Furthermore, in the substrate processing apparatus 2 described above, the modifying process and the heating process may be performed within the same processing container by, for example, changing the temperature of the stage 51 of the processing module 4. However, since it takes time to adjust the temperature of the stage 51, the modifying process and the heating process may be performed in different processing containers as described above. Furthermore, in the above example, the HF gas and the NH₃ gas are simultaneously supplied to the wafer W to perform the first COR processing, the respective gases may be supplied such that a period for supplying the HF gas and a period for supplying the NH₃ gas do not overlap each other, or such that the periods for supplying the respective gases overlap only partially. Even in this case, the first reaction product is produced by a reaction of one of the HF gas and the NH₃ gas adsorbed to the SiO₂ film 14 with the other gas.

FIG. 2B illustrates the protective film 15 as remaining on the wafer W after the etching process is completed. It is considered that the protective film 15 is very thin since it is formed on the surface layer of the SiN film 13 as described above. Thus, in practice, it is considered that the surface layer of the SiN film 13 is also slightly etched together with the SiO₂ film 14, so that the protective film 15 is removed upon completion of the etching. That is, it is not necessary to perform a removal process of removing the protective film 15 after completion of the etching. However, the removal process may be performed in order to more reliably prevent the influence of the protective film on each process after the etching. As this removal process, for example, a deprotection reaction may be performed by heating in the thermal processing module 30.

The configuration of the processing module 4 described in FIG. 5 and the processing performed in the processing module 4 will be described in more detail. As described above, by supplying TMSDMA gas to the wafer W in the processing container 41, the reaction described with reference to FIG. 3 occurs, and the SiN film 13 is silylated. During the silylation, dimethylamine (hereinafter, referred to as DMA) gas is generated, which is shown as X in FIG. 3.

As described above, after the silylation of the SiN film 13, HF gas is supplied to the wafer W in the processing container 41 in order to perform the first and second COR processings. The inventors have confirmed that if DMA gas remains in the processing container 41 when HF gas is supplied to the processing container 41, so that both HF gas and DMA gas are supplied to a member made of aluminum (Al) in the processing container 41, the surface of the member will be corroded. Examples of members made of Al include the inner wall of the processing container 41 and the gas shower head 56. Corrosion of these components generates Al fluoride, which vaporizes and adheres to the wafer W and various parts inside the processing chamber 11, so that metal contamination may be caused.

The gas supply paths 61 to 65 provided in the processing module 4 are each composed of a metal pipe, and the metal constituting this pipe contains Al. Thus, in order to prevent the above-mentioned contamination by Al, the gas supply path 61 for TMSDMA gas leading to the gas shower head 56 and the gas supply path 62 for HF gas leading to the gas shower head 56 are configured as separate members as shown in the drawings. Further, in the gas shower head 56, the flow path for TMSDMA gas and the flow path for HF gas are formed as separate flow paths that do not communicate with each other.

Further, the above-mentioned controller 20 controls the operation of the processing module 4 such that the above-mentioned Al contamination in the processing container 41 is prevented. Specifically, for example, the program in the controller 20 is configured to prevent a situation in which the valves included in the flow rate regulator 66 in the gas supply path 61 for TMSDMA gas and the valves included in the flow rate regulator 66 in the gas supply path 62 for HF gas are simultaneously opened to allow both gases to be supplied into the processing container 41. Further, for example, a user of the apparatus can set the supply period of each gas or change the previously set supply period by performing a predetermined operation from the controller 20. In that case, in order to prevent Al contamination in the processing container 41, the program may be configured so that the period during which TMSDMA gas is supplied into the processing container 41 and the period during which HF gas is supplied into the processing container 41 cannot be set to overlap.

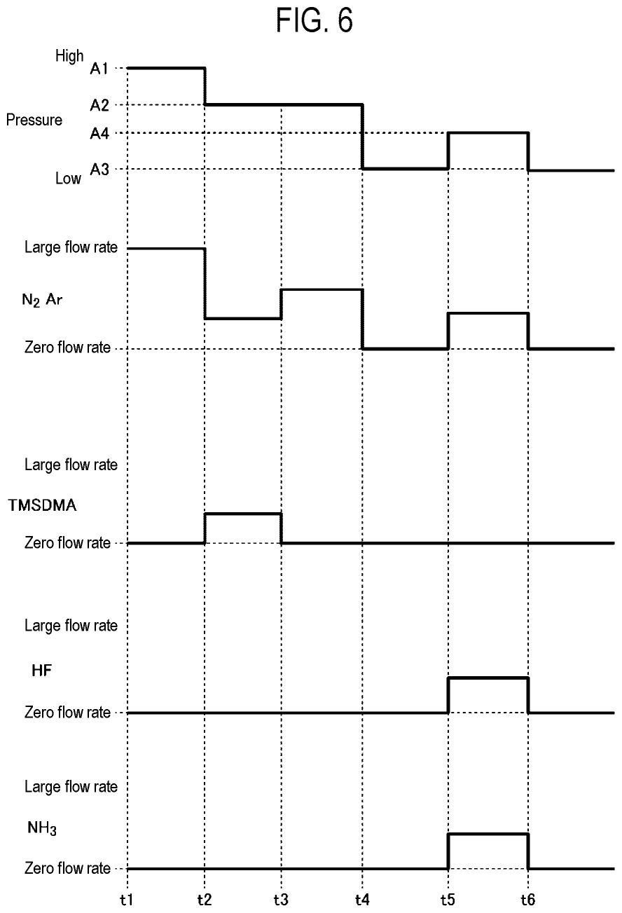

In order to prevent Al contamination in the processing container 41, it is preferable to supply each gas into the processing container 41 and process the wafer W as shown in the time chart of FIG. 6. This time chart shows the change in the supply amount of each gas into the processing container 41 and the presence or absence of supply, as well as the change in pressure inside the processing container 41. During the period from time t1 to time t6 shown in the time chart, the processing container 41 is constantly evacuated by the exhaust mechanism 55 to a vacuum pressure.

First, the wafer W loaded into the processing container 41 is placed on the stage 51 and its temperature is adjusted. On the other hand, inert gases N₂ gas and Ar gas are supplied into the processing container 41, and the pressure in the processing container 41 is set to A1 (time t1). At the following time t2, supply of TMSDMA gas into the processing container 41 is started, while the flow rates of N₂ gas and Ar gas supplied into the processing container 41 are reduced, and the pressure in the processing container 41 is reduced to A2.

At the following time t3, the supply of TMSDMA gas into the processing container 41 is stopped, while the flow rates of N₂ gas and Ar gas supplied into the processing container 41 are increased. The N₂ gas and Ar gas are used as purge gases to purge and remove the TMSDMA gas and DMA gas remaining in the processing container 41 from the processing container 41. Then, at time t4, the supply of N₂ gas and Ar gas into the processing container 41 is stopped, and the pressure in the processing container 41 drops to A3. As the exhaust continues in this manner, the degree of vacuum in the processing container 41 increases, and the removal of the TMSDMA gas and the DMA gas from the processing container 41 proceeds.

Then, at time t5, the supply of HF gas, NH₃ gas, N₂ gas, and Ar gas into the processing container 41 is started, and the pressure in the processing container 41 rises to A4. The first COR processing is performed with HF gas and NH₃ gas, and the SiO₂ film 14 is modified. By this time t5, the DMA gas and the TMSDMA gas, which is the source of DMA gas production, have been removed from the processing container 41, so that the corrosion of the inner wall of the processing container 41 and the surface of the gas shower head 56 is prevented even if HF gas is supplied in this manner. Then, at time t6, the supply of HF gas, NH₃ gas, N₂ gas, and Ar gas into the processing container 41 is stopped, the remaining gases in the processing container 41 are exhausted, and the wafer W is then removed from the processing container 41.

In addition to controlling the supply of each gas as described above in processing the wafer W, the inner wall of the processing container 41 and the surface of the gas shower head 56 may be coated with, for example, a Ni—P plating film to more reliably prevent corrosion. In the example shown in the time chart of FIG. 6, only the first COR processing using HF gas and NH₃ gas is performed among the first COR processing and the second COR processing, but as described above, the second COR processing may be performed by continuing the supply of HF gas after the first COR processing.

In addition, in the example of the chart of FIG. 6, in order to more reliably remove DMA gas and TMSDMA gas from the processing container 41, a period (time t4 to t5) is provided in which only the exhaust of the processing container 41 is performed among the supply of the purge gas, which is an inert gas, and the exhaust of the processing container 41. However, if, for example, the period (time t3 to t4) during which the purge gas is supplied and the processing container 41 is evacuated before the period (time t4 to t5) is set relatively long, so that the DMA gas and the TMSDMA gas can be sufficiently removed during the period from time t3 to t4, the period from time t4 to t5 during which only evacuation is performed without supplying the purge gas may not be provided. The supply of the purge gas into the processing container 41 and the evacuation of the processing container 41 during the period from time t3 to t4 correspond to the first removal process, and the evacuation of the processing container 41 during the period from time t4 to t5 corresponds to the second removal process.

In addition, the embodiments disclosed herein should be considered to be exemplary and not limitative in all respects. The above embodiments may be omitted, replaced, modified and combined in various ways without departing from the scope and spirit of the appended claims.

### [Evaluation Test]

An evaluation test performed in relation to the technology of the present disclosure will be described. In this evaluation test (Evaluation Test 1), the SiN film and the SiO₂ film were etched with the above-described process gas, and the etching amount at this time was evaluated with regard to a case where the protection process was performed and a case where the protection process was not performed, respectively. The SiN film and the SiO₂ film, which are evaluation targets, were those formed on a blanket wafer, respectively. The protection process was performed by using a TMSDMA liquid as the fluid including the silylating agent, and coating the wafer W with the liquid by the method described above.

Then, regardless of the presence or absence of the protection process, the etching process was performed by performing the modifying process (first COR processing and second COR processing) and the heating process, and the etching amount was measured. In addition, in the modifying process, an Ar gas and a N₂ gas were also supplied into the processing container together with the HF gas and the NH₃ gas.

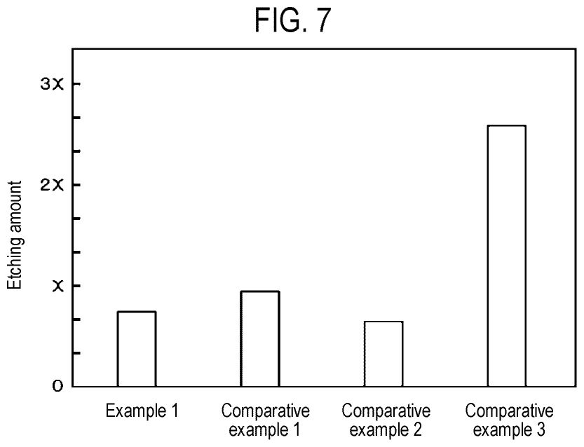

FIG. 7 illustrates the measured results of the etching amount. The vertical axis in the drawing is the etching amount. Further, “Example 1”, “Comparative Example 1”, “Comparative Example 2”, and “Comparative Example 3” illustrated on the horizontal axis are as follows.

### Example 1: SiN Film (with Protection Process)

### Comparative Example 1: SiN Film (without Protection Process)

### Comparative Example 2: SiO₂ Film (with Protection Process)

### Comparative Example 3: SiO₂ Film (without Protection Process)

From the measured results illustrated in FIG. 7, it was recognized that the etching amount of the SiN film was smaller in Example 1 in which the protection process was performed than in Comparative Example 1 in which the protection process was not performed, so that etching by the process gas (HF gas and NH₃ gas) may be suppressed by performing the protection process. On the other hand, it was confirmed that the SiO₂ film could be etched even if the protection process was performed.

Another evaluation test (Evaluation Test 2) is illustrated. In Evaluation Test 2, for the wafer W having the device structure illustrated in FIGS. 1A and 1B, a comparison was made between when the protection process and the etching process were performed and when the protection process was not performed and the etching process was performed, in the same manner as Evaluation Test 1. As a result, assuming that the etching amount of the SiN film 13 when the protection process was not performed was 1, the etching amount of the SiO₂ film 14 when the protection process was not performed was 1.24. Then, the etching amount of the SiN film 13 and the etching amount of the SiO₂ film 14 were 0.29 and 1.08, respectively, when the protection process was performed. In addition, the supply times of the process gas were approximately the same between when the protection process is performed and when the protection process is not performed, and the supply time of the process gas when the protection process is performed was 1.2 times longer than that when the protection process is not performed. The processing conditions other than the supply time of the process gas are the same in the respective cases. As described above, the results were such that the etching amount of the SiN film 13 was smaller than the etching amount of the SiO₂ film 14 while a change in the etching amount of the SiO₂ film 14 is suppressed even if the protective film is formed. Accordingly, from Evaluation Test 2, it was confirmed that selective etching of the SiO₂ film 14 is possible as described in the embodiment.

As described above, it is presumed that Evaluation Tests 1 and 2 gave different results with respect to the etching selectivity of the SiO₂ film 14, which is influenced by the difference in the surface structure of the wafer to which the silylating agent was supplied. However, as described above, in Evaluation Test 1, the etching amount of the SiN film 13 was reduced by the supply of the silylating agent, and also in Evaluation Test 2, the etching amount of the SiN film 13 was reduced by the supply of the silylating agent. Accordingly, taking Evaluation Tests 1 and 2 together into consideration, it was confirmed that forming the protective film for preventing the etching of the SiN film 13 is effective.

Next, Evaluation Test 3 will be described. In Evaluation Test 3-1, a substrate was placed on a stage 51 in processing container 41 of processing module 4, and each gas was supplied into processing container 41 according to the procedure described at times t1 to t6 in the time chart of FIG. 6. Thus, in Evaluation Test 3-1, each gas was supplied into processing container 41 such that the period during which TMSDMA gas was supplied did not overlap with the period during which HF gas and NH₃ gas were supplied. This series of gas supplies from times t1 to t6 constitutes one cycle, and the number of times the cycle was repeated was changed for each substrate. In other words, the number of times TMSDMA gas, HF gas, and NH₃ gas were supplied varied depending on the substrate. After a predetermined number of cycles were performed in this way, the substrate was removed from processing container 41, and the amount of Al atoms attached to each of the front and back surfaces of the substrate was measured.

In addition, in Evaluation Test 3-2, a test similar to Evaluation Test 3-1 was performed, except that TMSDMA gas, HF gas, and NH₃ gas were simultaneously supplied for a predetermined time as one cycle, and the amount of Al atoms attached to the substrate was measured. Thus, in Evaluation Test 3-2, TMSDMA gas, HF gas, and NH₃ gas were also supplied into the processing container 41 the same number of times as the number of cycles. The supply times of TMSDMA gas, HF gas, and NH₃ gas in one cycle were the same in Evaluation Tests 3-1 and 3-2. Therefore, when comparing Evaluation Tests 3-1 and 3-2, the more the number of cycles, the longer the interior of the processing container 41 is exposed to each of TMSDMA gas, HF gas, and NH₃ gas. In Evaluation Test 3-1, the number of cycles (number of cycles performed) was set to 1, 25, 50, 100, and 300, respectively, and gas was supplied to each substrate. In addition, the number of cycles in Evaluation Test 3-1 being 1 means that the series of gas supplies shown at times t1 to t6 was performed only once without repeating them. In Evaluation Test 3-2, the number of cycles was set to 5, 10, and 25, respectively.

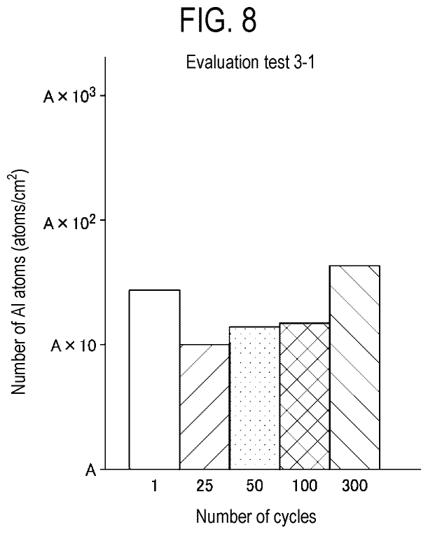

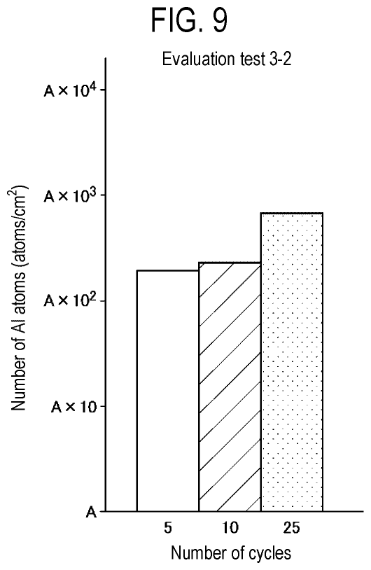

FIGS. 8 and 9 show graphs showing the results of Evaluation Tests 3-1 and 3-2 on the front side of the substrate, respectively, and represent the number of Al atoms (unit: atoms/cm²) measured for each number of cycles. “A” on the vertical axis of the graph is a positive number. Referring to the results of evaluation test 3-1 in FIG. 8, the measured value when the number of cycles is 1 is larger than the measured value when the number of cycles is 25 to 100, and is smaller than the measured value when the number of cycles is 300. Except for the result when the number of cycles is 1, in each graph, it can be seen that the measured value of the number of Al atoms generally tends to increase as the number of cycles increases in both evaluation tests 3-1 and 3-2. The number of Al atoms was smaller in the measurement results for each number of cycles in Evaluation Test 3-1 than in any number of cycles in Evaluation Test 3-2.

Although the results are not shown, the number of Al atoms on the back surface of the substrate also tended to generally increase as the number of cycles increased, similar to the front surface of the substrate, and the number of Al atoms on each number of cycles in Evaluation Test 3-1 was smaller than the number of Al atoms on any number of cycles in Evaluation Test 3-2. This shows that in order to prevent Al contamination in the processing container 41, it is effective to perform processing by supplying each gas to the wafer W as described in FIG. 6.

According to the present disclosure in some embodiments, in a substrate in which a first film and a second film, which are silicon-containing films of different types, are exposed on a surface, it is possible to selectively etch the first film, which is a silicon oxide film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method of supplying a process gas to a substrate, in which a first film and a second film that are silicon-containing films of different types are exposed on a surface, to selectively etch the first film that is a silicon oxide film, the method comprising:
a protection process of supplying a fluid containing a silylating agent to the substrate in order to form, on a surface layer of the second film, a protective film that prevents etching of the second film; and
an etching process of selectively etching the first film by supplying the process gas to the substrate having the protective film formed thereon.

2. The substrate processing method of claim 1, wherein the fluid containing the silylating agent is a gas containing the silylating agent.

3. The substrate processing method of claim 2, wherein the etching process includes:
a modifying process of modifying the first film by supplying the process gas; and
a heating process of heating the substrate to remove the modified first film.

4. The substrate processing method of claim 3, wherein the modifying process and the protection process are performed on the substrate within a same processing container.

5. The substrate processing method of claim 1, wherein the second film is a silicon nitride film.

6. The substrate processing method of claim 4, wherein the etching process is performed after the protection process,
wherein a first removal process in which an inert gas is supplied into the processing container while an inside of the processing container is evacuated is performed between the protection process and the etching process, in order to remove the gas containing the silylating agent from inside the processing container.

7. The substrate processing method of claim 6, wherein a second removal process in which the inside of the processing container is evacuated while the supply of the inert gas into the processing container is stopped is performed after the first removal process is performed and before the etching process is performed.

8. A substrate processing apparatus configured to supply a process gas to a substrate, in which a first film and a second film that are silicon-containing films of different types are exposed on a surface, to selectively etch the first film that is a silicon oxide film, the apparatus comprising:
a fluid supplier configured to supply a fluid containing a silylating agent to the substrate in order to form, on a surface layer of the second film, a protective film that prevents etching of the second film; and
a process gas supplier configured to selectively etch the first film by supplying the process gas to the substrate having the protective film formed thereon.

9. The substrate processing apparatus of claim 8, wherein the fluid containing the silylating agent is a gas containing the silylating agent,
the substrate processing apparatus further comprises:
an inert gas supplier for supplying an inert gas to the substrate;
a processing container having an inside in which the substrate is stored is evacuated and into which the gas containing the silylating agent supplied from the fluid supplier, the process gas supplied from the process gas supplier, and the inert gas supplied from the inert gas supplier are supplied; and
a controller configured to output a control signal so as to perform the following processes:
an etching process for supplying the process gas into the processing container after the gas containing the silylating agent is supplied into the processing container; and
a first removal process for supplying the inert gas into the processing container while the inside of the processing container is evacuated, between the supply of the gas containing the silylating agent into the processing container and the supply of the process gas in order to remove the gas containing the silylating agent from the processing container.

10. The substrate processing apparatus of claim 9, wherein a second removal process in which the inside of the processing container is evacuated while the supply of the inert gas into the processing container is stopped is performed after the first removal process is performed and before the etching process is performed.
